(19) United States
(12) Patent Application Publication
(10) Pub. No.: US 2020/0083094 A1
(43) Pub. Date: Mar. 12, 2020

(54) METHOD OF FABRICATING INTERCONNECTION LINE OF SEMICONDUCTOR DEVICE

(71) Applicant: SAMSUNG ELECTRONICS CO., LTD., Suwon-si (KR)

(72) Inventors: SHAO FENG DING, Hwaseong-si (KR); YOUNG SUK PARK, Hwaseong-si (KR); KYOUNG WOO LEE, Hwaseong-si (KR)

(21) Appl. No.: 16/287,406

(22) Filed: Feb. 27, 2019

(30) Foreign Application Priority Data
Sep. 11, 2018 (KR) 10-2018-0108352

(51) Int. Cl. H01L 21/768; H01L 23/522; H01L 23/532

(52) U.S. Cl. CPC H01L 21/76832; H01L 21/76831; H01L 21/7684; H01L 23/53238; H01L 21/76897; H01L 21/76807; H01L 23/5226; H01L 21/76871

(57) ABSTRACT

A method of fabricating an interconnection line of a semiconductor device includes forming a via and a lower interconnection trench in a first interlayer insulating layer, an etch stop layer, and a second interlayer insulating layer on a substrate, forming a lower diffusion barrier layer, a lower seed layer, and a lower interconnection layer inside the via and the lower interconnection trench, planarizing the lower interconnection layer using a chemical mechanical polishing (CMP) process to form a contact plug and a lower interconnection line, depositing a third interlayer insulating layer on top of a second interlayer insulating pattern and the lower interconnection line, forming an upper interconnection trench in the third interlayer insulating layer, forming an upper diffusion barrier layer, an upper seed layer, and an upper interconnection layer inside the upper interconnection trench, and planarizing the upper interconnection layer using a CMP process to form an upper interconnection line.

### CROSS-REFERENCE TO RELATED APPLICATION

This U.S. non-provisional patent application claims priority under 35 U.S.C. § 119 to Korean Patent Application No. 10-2018-0108352, filed on Sep. 11, 2018, in the Korean Intellectual Property Office (KIPO), the disclosure of which is incorporated by reference herein in its entirety.

### TECHNICAL FIELD

Example embodiments of the present inventive concept relate to a method of fabricating an interconnection line of a semiconductor device, and the interconnection line of the semiconductor device fabricated using the method.

### DISCUSSION OF RELATED ART

It is necessary to fabricate reliable interconnection lines to increase performance of semiconductor devices with higher integration density. Recently, there is an increase in applying copper interconnection lines having relatively low resistances to the fabrication of the interconnection lines of the semiconductor devices. Since the copper interconnection lines may not be smoothly dry etched, they are usually formed by a Damascene process. The copper interconnection line formed by the damascene process may be electrically connected to an underlying substrate or a conductive pattern through a contact plug. Since the copper interconnection line and the contact plug may be formed of different materials using separate processes, a contact resistance between the copper interconnection line and the contact plug may increase accordingly.

### SUMMARY

Example embodiments of the present inventive concept provide a method of fabricating a reliable interconnection line of a semiconductor device, and the reliable interconnection line of the semiconductor device fabricated using the method.

According to an example embodiment of the present inventive concept, there is provided a method of fabricating an interconnection line of a semiconductor device. The method includes depositing a first interlayer insulating layer, an etch stop layer, and a second interlayer insulating layer sequentially on a substrate in which a conductive pattern is formed, and forming a via photoresist pattern on a top surface of the second interlayer insulating layer, forming a via in the first interlayer insulating layer, the etch stop layer, and the second interlayer insulating layer using the via photoresist pattern as an etch mask so as to form a first interlayer insulating pattern, an etch stop pattern, and a second interlayer insulating pattern, the via exposing a top surface of the substrate or the conductive pattern, forming a lower photoresist pattern on a top surface of the second interlayer insulating pattern and forming a lower interconnection trench in the second interlayer insulating pattern using the lower photoresist pattern as an etch mask, the lower interconnection trench exposing portions of top surfaces of the via and the etch stop pattern, forming a lower diffusion barrier layer, a lower seed layer, and a lower interconnection layer sequentially inside the via and the lower interconnection trench, planarizing the lower interconnection layer using a chemical mechanical polishing (CMP) process to form a contact plug in the via and a lower interconnection line in the lower interconnection trench, depositing a third interlayer insulating layer on top surfaces of the second interlayer insulating pattern and the lower interconnection line and forming an upper photoresist pattern on a top surface of the third interlayer insulating layer, forming an upper interconnection trench in the third interlayer insulating layer using the upper photoresist pattern as an etch mask to form a third interlayer insulating pattern, the upper interconnection trench exposing the top surface of the lower interconnection line, forming an upper diffusion barrier layer, an upper seed layer, and an upper interconnection layer sequentially inside the upper interconnection trench, and planarizing the upper interconnection layer using a CMP process to form an upper interconnection line.

According to an example embodiment of the present inventive concept, there is provided a method of fabricating an interconnection line of a semiconductor device. The method includes depositing a lower interlayer insulating layer on a substrate in which a conductive pattern is formed, and forming a via photoresist pattern on a top surface of the lower interlayer insulating layer, forming a via in the lower interlayer insulating layer using the via photoresist pattern as an etch mask to form a lower interlayer insulating pattern, the via exposing a top surface of the substrate or the conductive pattern, forming a via filling layer in the via and forming a lower photoresist pattern on a region including the via filling layer over the lower interlayer insulating pattern, etching the lower interlayer insulating pattern and the via filling layer using the lower photoresist pattern as an etch mask to form a lower interconnection trench in the lower interlayer insulating pattern on the via, removing the lower photoresist pattern and the via filling layer remaining in the via and forming a lower diffusion barrier layer, a lower seed layer, and a lower interconnection layer sequentially inside the via and the lower interconnection trench, planarizing the lower interconnection layer using a CMP process to form a contact plug in the via and a lower interconnection line in the lower interconnection trench, depositing an upper interlayer insulating layer on top surfaces of the lower interlayer insulating pattern and the lower interconnection line, and forming an upper photoresist pattern on a top surface of the upper interlayer insulating layer, forming an upper interconnection trench in the upper interlayer insulating layer using the upper photoresist pattern as an etch mask, the upper interconnection trench exposing the top surface of the lower interconnection line, forming an upper diffusion barrier layer, an upper seed layer, and an upper interconnection layer sequentially inside the upper interconnection trench, and planarizing the upper interconnection layer using a CMP process to form an upper interconnection line.

According to an example embodiment of the present inventive concept, there is provided a method of fabricating an interconnection line of a semiconductor device. The method includes depositing a lower interlayer insulating layer on a substrate in which a conductive pattern is formed, and forming a lower photoresist pattern on a top surface of the lower interlayer insulating layer, forming a lower interconnection trench in the lower interlayer insulating layer using the lower photoresist pattern as an etch mask, forming a lower trench filling layer inside the lower interconnection trench and forming a via photoresist pattern on a top surface of the lower trench filling layer, sequentially etching the lower trench filling layer and the lower interlayer insulating layer using the via photoresist pattern as an etch mask to form a via hole passing through a bottom surface of the lower interlayer insulating layer so that the lower interlayer insulating layer is patterned to form a lower interlayer insulating pattern, removing the lower trench filling layer and the via photoresist pattern and forming a via in the lower interlayer insulating pattern, forming a lower diffusion barrier layer, a lower seed layer, and a lower interconnection layer sequentially inside the via and the lower interconnection trench, planarizing the lower interconnection layer using a CMP process to form a contact plug in the via and a lower interconnection line in the lower interconnection trench, depositing an upper interlayer insulating layer on top surfaces of the lower interlayer insulating pattern and the lower interconnection line and forming an upper photoresist pattern on a top surface of the upper interlayer insulating layer, forming an upper interconnection trench in the upper interlayer insulating layer using the upper photoresist pattern as an etch mask, the upper interconnection trench exposing the top surface of the lower interconnection line, forming an upper diffusion barrier layer, an upper seed layer, and an upper interconnection layer sequentially inside the upper interconnection trench, and planarizing the upper interconnection layer using a CMP process to form an upper interconnection line.

### BRIEF DESCRIPTION OF THE DRAWINGS

Example embodiments of the present inventive concept will be more clearly understood from the following detailed description taken in conjunction with the accompanying drawings, in which:

FIGS. 1A to 1I are vertical cross-sectional views illustrating processes of a method of fabricating an interconnection line of a semiconductor device according to an example embodiment of the present inventive concept;

FIG. 2A is a vertical cross-sectional view of an interconnection line of a semiconductor device according to an example embodiment of the present inventive concept;

FIG. 2B is a vertical cross-sectional view of an interconnection line of a semiconductor device according to an example embodiment of the present inventive concept;

FIGS. 3A to 3F are vertical cross-sectional views illustrating processes of a method of fabricating an interconnection line of a semiconductor device according to an example embodiment of the present inventive concept; and

FIGS. 4A to 4E are vertical cross-sectional views illustrating processes of a method of fabricating an interconnection line of a semiconductor device according to an example embodiment of the present inventive concept.

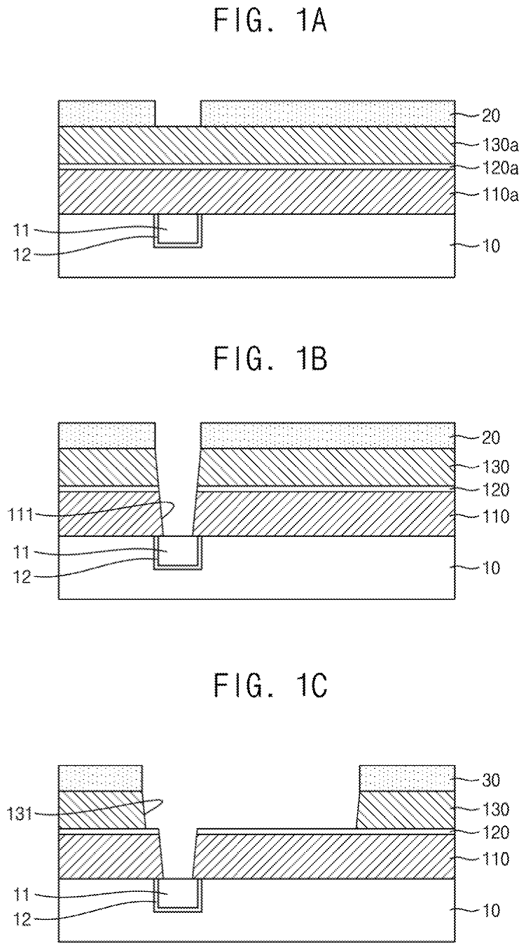

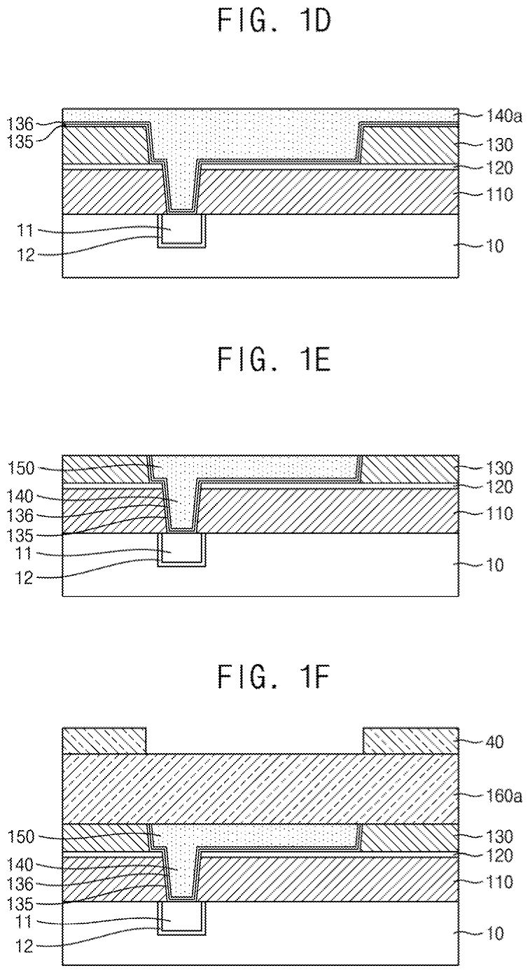

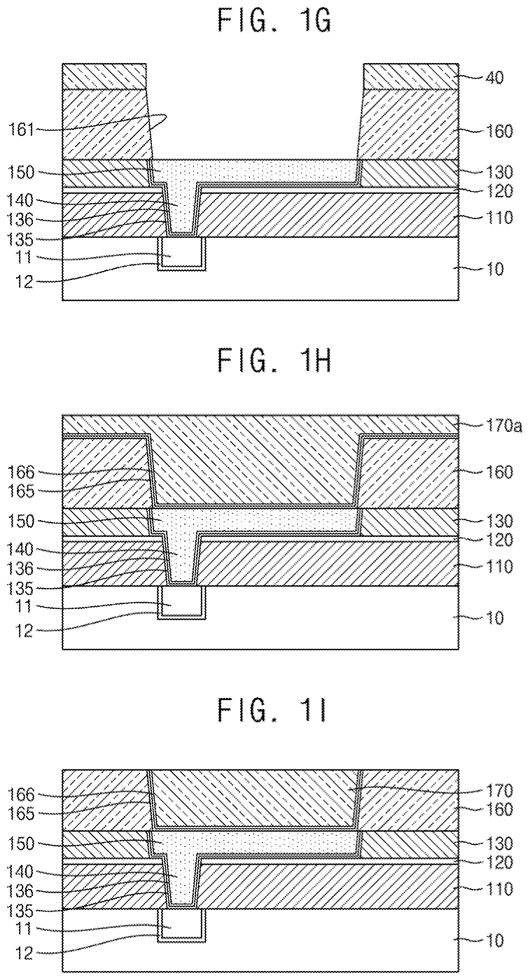

Since the drawings in FIGS. 1A-4E are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

Hereinafter, example embodiments of the present inventive concept relate to a method of fabricating an interconnection line of a semiconductor device and the interconnection line of the semiconductor device fabricated using the method will be described.

To begin with, a method of fabricating an interconnection line of a semiconductor device according to an example embodiment of the present inventive concept will be described.

FIGS. 1A to 1I are vertical cross-sectional views illustrating processes of a method of fabricating an interconnection line of a semiconductor device according to an example embodiment of the present inventive concept.

The method of fabricating an interconnection line of a semiconductor device according to an example embodiment of the present inventive concept may be a method of forming a copper interconnection line to be electrically connected to a substrate 10 or a conductive pattern 11 formed in the substrate 10 (or an insulating layer formed on the substrate 10). The substrate 10 may be a silicon (Si) substrate, a silicon on insulator (SOI) substrate, a gallium arsenide (GaAs) substrate, a silicon germanium (SiGe) substrate, a ceramic substrate, a quartz substrate, or a glass substrate. The substrate 10 may include the insulating layer deposited on a top surface of the substrate 10 to have a height the same as that of the conductive pattern 11. Further, the substrate 10 may be a semiconductor substrate in which source and drain regions are formed. In an example embodiment of the present inventive concept, the substrate 10 may include one or more semiconductor layers or structures, and may include active or operable portions of semiconductor devices. The conductive pattern 11 may include a conductive contact, a conductive interconnection line, or a conductive plug. The conductive pattern 11 may be a conductive contact electrically connected to the source/drain regions. The conductive pattern 11 may be formed of, for example, a tungsten (W), titanium (Ti), copper (Cu), or aluminum (Al) material. The conductive contact may be formed of a titanium (Ti) material. A pattern diffusion barrier layer 12 may be formed on a bottom surface and a side surface of the conductive pattern 11 according to a material forming the conductive pattern 11. Any suitable material may be used for the pattern diffusion barrier layer 12. For example, when the conductive pattern 11 is formed of titanium (Ti), the pattern diffusion barrier layer 12 may be formed of titanium nitride (TiN).

In the method of fabricating an interconnection line of a semiconductor device according to an example embodiment of the present inventive concept, the interconnection line of the semiconductor device may be formed to include a contact plug electrically connected to the substrate 10 or the conductive pattern 11, a lower interconnection line integrally formed with the contact plug on the contact plug, and an upper interconnection line formed in contact with the lower interconnection line. The contact plug, the lower interconnection line, and the upper interconnection line may be formed using a dual Damascene process and a single Damascene process. More specifically, the contact plug and the lower interconnection line may be formed using a dual Damascene process, and the upper interconnection line may be formed using a single Damascene process. All of the contact plug, the lower interconnection line, and the upper interconnection line may be formed of the same material. For example, all of the contact plug, the lower interconnection line, and the upper interconnection line may be formed of copper (Cu). The lower interconnection line may be electrically connected to the upper interconnection line, thereby forming a device interconnection line having a predetermined thickness required for the semiconductor device. The lower interconnection line may be formed to have a thickness smaller than that of the upper interconnection line. Since the lower interconnection line and the upper interconnection line are formed of a copper (Cu) material, the lower and upper interconnection lines may be formed using an electroplating process. The lower interconnection line may be formed to such a thickness that the entire lower interconnection line may be uniformly formed without creating defects in the electroplating process. For example, the lower interconnection line having a proper thickness and the contact plug may be uniformly electroplated with copper (Cu) in the same electroplating process without creating defects.

Referring to FIG. 1A, the conductive pattern 11 may be formed in the substrate 10. A first interlayer insulating layer 110a, an etch stop layer 120a, and a second interlayer insulating layer 130a may be sequentially deposited on the substrate 10 and the conductive pattern 11. A via photoresist pattern 20 may be formed on a top surface of the second interlayer insulating layer 130a. Meanwhile, when necessary, a diffusion barrier layer or an etch stop layer may be further formed under the first interlayer insulating layer 110a. Further, an anti-reflection layer (ARL) for a photoresist process may be formed under the via photoresist pattern 20. In addition, a capping layer may be further formed under the via photoresist pattern 20 so that damage to the second interlayer insulating layer 130a may be prevented in a subsequent chemical mechanical polishing (CMP) process.

The first interlayer insulating layer 110a may be formed to have a thickness different from that of the second interlayer insulating layer 130a. For example, the second interlayer insulating layer 130a may be formed to have a thickness smaller than that of the first interlayer insulating layer 110a. Since a height of the contact plug to be formed subsequently depends on a thickness of the first interlayer insulating layer 110a, the first interlayer insulating layer 110a may be formed to have an appropriate height according to the height of the contact plug to be formed. Since a height of the lower interconnection line to be formed subsequently depends on a thickness of the second interlayer insulating layer 130a, the second interlayer insulating layer 130a may be formed to have an appropriate height according to the height of the lower interconnection line to be formed.

The first interlayer insulating layer 110a may be formed of an inorganic low-k dielectric material. The second interlayer insulating layer 130a may be formed of a material the same as that of the first interlayer insulating layer 110a. The first interlayer insulating layer 110a and the second interlayer insulating layer 130a may be formed of a material such as, for example, silicon oxycarbide (SiOC), silicon dioxide (SiO₂), silicon oxynitride (SiON), siloxane spin-on-glass (SOG), silicate SOG, phosphosilicate glass (PSG), plasma enhanced oxide (PEOX), p-tetraethyl orthosilicate (P-TEOS), and undoped silicate glass (USG). Further, the second interlayer insulating layer 130a may be a doped oxide-based low-k dielectric film containing H, C, or CHₓ. The first interlayer insulating layer 110a and the second interlayer insulating layer 130a may be formed by a process such as, for example, a chemical vapor deposition (CVD) process, a sputtering process, a spin coating process, or an atomic layer deposition (ALD) process.

The etch stop layer 120a may be formed of a non-oxide material, and may be a nitride layer formed of, for example, a silicon nitride (Si₃N₄) or boron nitride (BN) material or a carbide layer formed of, for example, a silicon carbide (SiC) material. The etch stop layer 120a may be formed by a process such as, for example, a CVD process, a sputtering process, or an ALD process. The etch stop layer 120a may prevent the etching of the first interlayer insulating layer 110a during a process of forming a lower interconnection trench 131, which will be described below, in the second interlayer insulating layer 130a.

The via photoresist pattern 20 may be a pattern formed by a typical photolithography process. For example, the formation of the via photoresist pattern 20 may include coating the top surface of the second interlayer insulating layer 130a with a photoresist layer, exposing the photoresist layer using a photomask, and then developing the exposed photoresist layer with a developer. The via photoresist pattern 20 may include an opening corresponding to a plan view of a via to be formed in the first interlayer insulating layer 110a.

Referring to FIG. 1B, the first interlayer insulating layer 110a, the etch stop layer 120a, and the second interlayer insulating layer 130a may be etched using the via photoresist pattern 20 as an etch mask, thereby forming a via 111. The via 111 may be formed to pass through the first interlayer insulating layer 110a, the etch stop layer 120a, and the second interlayer insulating layer 130a and expose a top surface of the substrate 10 or the conductive pattern 11. The first interlayer insulating layer 110a, the etch stop layer 120a, and the second interlayer insulating layer 130a may be anisotropically etched to form the via 111. The anisotropic etching process may include a reactive ion etching (RIE) process.

Due to the formation of the via 111, the first interlayer insulating layer 110a, the etch stop layer 120a and the second interlayer insulating layer 130a may be patterned to form a first interlayer insulating pattern 110, an etch stop pattern 120 and a second interlayer insulating pattern 130, respectively. Meanwhile, after the via 111 is formed, the via photoresist pattern 20 may be removed by an ashing strip process.

Referring to FIG. 1C, a lower photoresist pattern 30 may be formed on a top surface of the second interlayer insulating pattern 130. A lower interconnection trench 131 may be formed in the second interlayer insulating pattern 130 using the lower photoresist pattern 30 as an etch mask to expose portions of top surfaces of the via 111 and the etch stop pattern 120. Since via 111 is an empty space, the top surface may mean a top border of the via 111.

The lower photoresist pattern 30 may be a pattern formed by a typical photolithography process. For example, the formation of the lower photoresist pattern 30 may include coating a top surface of the second interlayer insulating pattern 130 with a photoresist layer, exposing the photoresist layer using a photomask, and then developing the exposed photoresist layer with a developer. The lower photoresist pattern 30 may have an opening larger than that of the via 111. The lower photoresist pattern 30 may have an opening corresponding to a plan view of the lower interconnection trench 131 or the lower interconnection line to be formed. The lower interconnection trench 131 may be formed on a region including the via 111 over the via 111. The lower interconnection trench 131 may expose an upper portion of the via 111 and a portion of the top surface of the etch stop pattern 120, and may be connected to the via 111 at the upper portion of the via 111. A height of the lower interconnection trench 131 may be smaller than a height of the via 111, and a width of the lower interconnection trench 131 may be greater than a diameter or width of the via 111. The lower interconnection trench 131 may form a dual Damascene structure along with the via 111. The lower interconnection trench 131 may be formed to have a height smaller than that of the via 111 and a width greater than that of the via 111. For example, the via 111 may be connected to the conductive pattern 11 under the lower interconnection trench 131, and may be formed to have a depth greater than that of the lower interconnection trench 131. Since the lower interconnection trench 131 is formed to have a small depth and a large width, a copper (Cu) material may easily flow into the underlying via 111 during a subsequent process of electroplating the copper (Cu) material so that possibility of creating defects in a copper (Cu) plating layer formed in the via 111 may be reduced. Meanwhile, the lower photoresist pattern 30 may be removed by an ashing strip process.

Referring to FIG. 1D, a lower diffusion barrier layer 135, a lower seed layer 136, and a lower interconnection layer 140a may be sequentially formed inside the via 111 and the lower interconnection trench 131. That is, the lower diffusion barrier layer 135 and the lower seed layer 136 may be conformally formed on a region including the top surface of the substrate 10 or the conductive pattern 11 exposed by the via 111 and inner side surfaces of the first interlayer insulating pattern 110, the etch stop pattern 120, and the second interlayer insulating pattern 130. The lower interconnection layer 140a may be formed on a surface of the lower seed layer 136 by filling the via 111 and the lower interconnection trench 131. The lower interconnection layer 140a may be formed to a level higher than that of the top surface of the lower seed layer 136 to ensure that the via 111 and the lower interconnection trench 131 are completely filled. The lower diffusion barrier layer 135, the lower seed layer 136, and the lower interconnection layer 140a may also be formed on the top surface of the second interlayer insulating pattern 130.

The lower diffusion barrier layer 135 may be conformally formed on a region including the top surface of the conductive pattern 11 exposed by the via 111, the inner side surfaces of the first interlayer insulating pattern 110, the etch stop pattern 120, and the second interlayer insulating pattern 130, and the top surface of the second interlayer insulating pattern 130. The lower seed layer 136 may be conformally deposited on a surface of the lower diffusion barrier layer 135.

The lower diffusion barrier layer 135 may be formed of a material such as, for example, titanium (Ti), titanium nitride (TiN), tungsten (W), tungsten nitride (WN), a titanium tungsten (TiW) alloy, chromium (Cr), chromium nitride (CrN), tantalum (Ta), or tantalum nitride (TaN). The lower diffusion barrier layer 135 may be formed to have a thickness of about 30 Å to 300 Å. The lower diffusion barrier layer 135 may be formed by a process such as, for example, a CVD process, a sputtering process, or an ALD process. The lower diffusion barrier layer 135 may prevent the copper (Cu) material of the lower interconnection layer 140a from being diffused in the vicinity of the via 111 and the lower interconnection trench 131.

The lower seed layer 136 may be formed of a copper (Cu) material. The lower seed layer 136 may be deposited on the surface of the lower diffusion barrier layer 135. The lower seed layer 136 may be formed by a CVD process or an electroless plating process. The lower seed layer 136 may be formed to have a thickness of about 100 Å to 300 Å.

The lower interconnection layer 140a may be plated on the surfaces of the lower diffusion barrier layer 135 and the lower seed layer 136 to fill the via 111 and the lower interconnection trench 131. The lower interconnection layer 140a may be formed by an electroplating process. Meanwhile, since the lower interconnection trench 131 is formed to have a relatively small depth and a relatively large width according to the present example embodiment described above, possibility of creating defects in the copper (Cu) plating layer formed in the via 111 may be reduced. On the contrary, if the lower interconnection trench 131 were formed to have a relatively large depth, an entrance of the via 111 may be plated prior to a bottom of the via 111 during the process of simultaneously plating the via 111 and the lower interconnection trench 131 with the copper (Cu) material, defects such as voids may occur inside the via 111. This phenomenon may get worse as the depth of the lower interconnection trench 131 increases.

Referring to FIG. 1E, the lower interconnection layer 140a may be planarized by a CMP process to form a contact plug 140 and a lower interconnection line 150. A region including a portion of the lower interconnection layer 140a, which is exposed above the second interlayer insulating pattern 130, may be planarized. In this case, the second interlayer insulating pattern 130 may be planarized together with the lower interconnection layer 140a to expose the top surface of the second interlayer insulating pattern 130.

The contact plug 140 may be formed in the via 111 of the first interlayer insulating pattern 110, and the lower interconnection line 150 may be formed in the lower interconnection trench 131 of the second interlayer insulating pattern 130. The contact plug 140 may be in contact with the substrate 10 or the conductive pattern 11. The contact plug 140 and the lower interconnection line 150 may be integrally formed in a single process. For example, the contact plug 140 and the lower interconnection line 150 may be formed by a dual Damascene process. The lower interconnection line 150 may be formed to have a height smaller than that of the contact plug 140 and a width greater than that of the contact plug 140. The lower interconnection line 150 may serve to increase a contact area between an upper interconnection line to be formed on the lower interconnection line 150 and the contact plug 140. Since the contact plug 140 and the lower interconnection line 150 are integrally formed of the same material according to the present example embodiment, there is no contact resistance issue between the contact plug 140 and the lower interconnection line 150. On the contrary, if the lower interconnection line 150 and the contact plug 140 were formed of different materials using separate processes, a contact resistance between the lower interconnection line 150 and the contact plug 140 may increase.

Referring to FIG. 1F, a third interlayer insulating layer 160a may be deposited on the top surface of the second interlayer insulating pattern 130 and a top surface of the lower interconnection line 150, and an upper photoresist pattern 40 may be formed on a top surface of the third interlayer insulating layer 160a.

The third interlayer insulating layer 160a may be formed of a material and by a process the same as those of the second interlayer insulating layer 130a. The third interlayer insulating layer 160a may be formed to have a thickness greater than that of the second interlayer insulating layer 130a. The third interlayer insulating layer 160a may be formed to have an appropriate thickness in consideration of a thickness of the upper interconnection line to be formed.

The upper photoresist pattern 40 may be a pattern formed by a typical photolithography process. For example, the formation of the upper photoresist pattern 40 may include coating the top surface of the second interlayer insulating pattern 130 with a photoresist layer, exposing the photoresist layer using a photomask, and then developing the exposed photoresist layer with a developer. The upper photoresist pattern 40 may have an opening corresponding to a plan view of an upper interconnection trench 161 or the upper interconnection line to be formed. In an example embodiment of the present inventive concept, the upper photoresist pattern 40 may be formed to have a shape the same as that of the lower photoresist pattern 30. That is, the upper photoresist pattern 40 may be formed using a photomask the same as that used in forming the lower photoresist pattern 30. In this case, the upper interconnection trench 161 may be formed to have a plan view the same as that of the lower interconnection trench 131. Further, since the photomask for forming the lower photoresist pattern 30 is the same as the photomask for forming the upper photoresist pattern 40, process efficiency may increase.

In an example embodiment of the present inventive concept, the opening of the upper photoresist pattern 40 may have a width larger than that of the opening of the lower photoresist pattern 30. In this case, the upper interconnection trench 161 may be formed to have a width greater than that of the lower interconnection trench 131. Here, the width of the opening may refer to a size of the opening in a direction perpendicular to a lengthwise direction in which the upper interconnection trench 161 and the lower interconnection trench 131 extend.

Referring to FIG. 1G, the upper interconnection trench 161 may be formed using the upper photoresist pattern 40 as an etch mask to expose a top surface of the lower interconnection line 150 in the third interlayer insulating layer 160a. Due to the formation of the upper interconnection trench 161, the third interlayer insulating layer 160a may be patterned to form a third interlayer insulating pattern 160. The upper interconnection trench 161 may be formed to pass through the third interlayer insulating layer 160a and expose at least a portion of the lower interconnection line 150. In an example embodiment of the present inventive concept, the upper interconnection trench 161 may have a plan view the same as that of the top surface of the lower interconnection line 150. For example, the upper interconnection trench 161 may be formed to have a width and a length the same as those of the lower interconnection trench 131. In this case, the upper interconnection trench 161 may expose the entire top surface of the lower interconnection line 150.

In an example embodiment of the present inventive concept, the upper interconnection trench 161 may be formed to have an area greater than that of the lower interconnection trench 131. For example, the upper interconnection trench 161 may be formed to have a width greater than that of the lower interconnection trench 131. In this case, the upper interconnection trench 161 may expose both the top surface of lower interconnection line 150 and a portion of the top surface of the second interlayer insulating pattern 130.

The upper interconnection trench 161 may be formed to have a depth greater than that of the lower interconnection trench 131. Unlike the lower interconnection trench 131, a structure, such as a via 111 having a small width, may not be formed under the upper interconnection trench 161. Accordingly, the upper interconnection trench 161 may be efficiently filled with a copper (Cu) material during an electroplating process, and possibility of creating defects may be reduced.

Referring to FIG. 1H, an upper diffusion barrier layer 165, an upper seed layer 166, and an upper interconnection layer 170a may be sequentially formed on the top surface of the lower interconnection line 150, which is exposed by the upper interconnection trench 161 and inside the upper interconnection trench 161. The upper diffusion barrier layer 165, the upper seed layer 166, and the upper interconnection layer 170a may also be formed on the top surface of the third interlayer insulating pattern 160.

The upper diffusion barrier layer 165 may be conformally deposited on a region including the top surface of the lower interconnection line 150, which is exposed by the upper interconnection trench 161, an inner side surface of the third interlayer insulating pattern 160, and the top surface of the third interlayer insulating pattern 160. The upper seed layer 166 may be conformally deposited on a surface of the upper diffusion barrier layer 165. The upper diffusion barrier layer 165 and the upper seed layer 166 may be formed of a material using a process the same as those of the lower diffusion barrier layer 135 and the lower seed layer 136, respectively. The upper interconnection layer 170a may be deposited on surfaces of the upper diffusion barrier layer 165 and the upper seed layer 166 to fill the upper interconnection trench 161. The upper interconnection layer 170a may be formed by an electroplating process. The upper interconnection layer 170a may be formed to a level higher than that of the top surface of the upper seed layer 166 to ensure that the upper interconnection trench 161 is completely filled.

Referring to FIG. 1I, the upper interconnection layer 170a may be planarized by a CMP process to form an upper interconnection line 170. Further, the third interlayer insulating pattern 160 may also be planarized to expose the top surface of the third interlayer insulating pattern 160. A region of the upper interconnection layer 170a, which is exposed over the third interlayer insulating pattern 160, may be removed and planarized to form the upper interconnection line 170. Thus, the upper interconnection line 170 may be formed by a single Damascene process. In an example embodiment of the present inventive concept, the upper interconnection line 170 may have a plan view the same as that of the lower interconnection line 150. However, the present inventive concept is not limited thereto. For example, in an example embodiment of the present inventive concept, the upper interconnection line 170 may be formed to have an area greater than that of the lower interconnection line 150. In this case, since the entire top surface of the lower interconnection line 150 is in contact with a bottom surface of the upper interconnection line 170, a contact resistance between the lower interconnection line 150 and the upper interconnection line 170 may be reduced. The upper interconnection line 170 may be formed to have a height greater than that of the lower interconnection line 150.

Next, an interconnection line of a semiconductor device according to an example embodiment of the present inventive concept will be described.

Referring to FIG. 1I, the interconnection line of the semiconductor device according to an example embodiment of the present inventive concept may include a first interlayer insulating pattern 110, an etch stop pattern 120, a second interlayer insulating pattern 130, a contact plug 140, a lower interconnection line 150, a third interlayer insulating pattern 160, and an upper interconnection line 170.

In the interconnection line of the semiconductor device, the contact plug 140, the lower interconnection line 150, and the upper interconnection line 170 may each be formed of a copper (Cu) material. The contact plug 140 may be integrally formed with the lower interconnection line 150, and the upper interconnection line 170 may be formed over the lower interconnection line 150. A lower seed layer 136 and a lower diffusion barrier layer 135 may be formed on an outer surface (i.e., a bottom surface and a side surface) of the contact plug 140. The lower seed layer 136 and the lower diffusion barrier layer 135 may be formed on an outer surface (i.e., a side surface) of the lower interconnection line 150. The copper (Cu) material may be exposed at a top surface of the lower interconnection line 150. The upper seed layer 166 and the upper diffusion barrier layer 165 may be formed on an outer surface (i.e., a bottom surface and a side surface) of the upper interconnection line 170. The upper diffusion barrier layer 165 of the upper interconnection line 170 may be in direct contact with the top surface of the lower interconnection line 150.

The lower interconnection line 150 and the upper interconnection line 170 may have the same plan view, and may be electrically connected to each other or in contact with each other in a vertical direction. The interconnection line of the semiconductor device may be formed to have a required thickness by controlling relative thicknesses of the upper interconnection line 170 and the lower interconnection line 150. In the interconnection line of the semiconductor device, the upper interconnection line 170 may be formed to have a relatively great thickness, and the lower interconnection line 150 may be formed to have a relatively small thickness. In this case, since a lower interconnection trench 131 for the lower interconnection line 150 has a small depth, even when a via 111 for forming the contact plug 140 has a small diameter and a great depth, possibility of creating defects in the contact plug 140 and the lower interconnection line 150 during an electroplating process may be reduced. If the lower interconnection line 150 and the contact plug 140 were formed of different materials using separate processes, a contact resistance between the lower interconnection line 150 and the contact plug 140 may increase. In the present example embodiment, the contact plug 140 and the lower interconnection line 150 are integrally formed in a single process, for example, a dual Damascene process, and may be formed of copper (Cu), and thus the contact resistance between the lower interconnection line 150 and the contact plug 140 may not increase.

After the top surface of the lower interconnection line 150 is planarized by a CMP process, the upper interconnection line 170 may be formed. Here, the upper interconnection line 170 may be formed by a single Damascene process, and may be formed of copper (Cu). Thus, an electrical contact of the lower interconnection line 150 with the upper interconnection line 170 may be enhanced, and a contact resistance between the lower interconnection line 150 and the upper interconnection line 170 may be reduced.

The first interlayer insulating pattern 110 may be deposited to have a predetermined thickness on a top surface of a substrate 10. The thickness of the first interlayer insulating pattern 110 may be determined in consideration of the height of the contact plug 140. The first interlayer insulating pattern 110 may include the via 111, which is formed to pass through the first interlayer insulating pattern 110 from a top surface of the first interlayer insulating pattern 110 to a bottom surface thereof. The via 111 may expose the substrate 10 or a conductive pattern 11 formed on the top surface of the substrate 10.

The etch stop pattern 120 may be formed on the top surface of the first interlayer insulating pattern 110. The via 111 may be formed to pass though the etch stop pattern 120 from a top surface of the etch stop pattern 120 to a bottom surface thereof. The second interlayer insulating pattern 130 may be formed to have a predetermined thickness on the top surface of the etch stop pattern 120. The thickness of the second interlayer insulating pattern 130 may be determined in consideration of the thickness of the lower interconnection line 150. The second interlayer insulating pattern 130 may be formed to have a thickness smaller than that of the first interlayer insulating pattern 110. The second interlayer insulating pattern 130 may include the lower interconnection trench 131, which is formed to pass through the second interlayer insulating pattern 130 from a top surface of the second interlayer insulating pattern 130 to a bottom surface thereof. The lower interconnection trench 131 may be connected to the via 111 at an upper portion of the via 111. The lower interconnection trench 131 may be formed to have a length, a width, and a shape, which are required for the interconnection line of the semiconductor device.

The contact plug 140 may be formed by filling the via 111 with a copper (Cu) material. That is, a bottom surface of the contact plug 140 may be in contact with the underlying substrate 10 or conductive pattern 11 and electrically connected to the underlying substrate 10 or conductive pattern 11.

The lower interconnection line 150 may be formed by filling the lower interconnection trench 131 with a copper (Cu) material. The lower interconnection line 150 may be integrally formed with the contact plug 140. The lower interconnection line 150 may have a predetermined width, length, and height.

The third interlayer insulating pattern 160 may be deposited on a top surface of the second interlayer insulating pattern 130. The third interlayer insulating pattern 160 may have a shape the same as that of the second interlayer insulating pattern 130. The third interlayer insulating pattern 160 may include an upper interconnection trench 161, which may be formed to pass through the third interlayer insulating pattern 160 from a top surface of the third interlayer insulating pattern 160 to a bottom surface thereof, and the upper interconnection trench 161 may be connected to the lower interconnection trench 131. The upper interconnection trench 161 may be positioned over the lower interconnection trench 131, and may have a plan view the same as that of the lower interconnection trench 131. That is, the upper interconnection trench 161 may be formed to have a width and a length the same as those of the lower interconnection trench 131. Meanwhile, the upper interconnection trench 161 may have a depth greater than that of the lower interconnection trench 131.

The upper interconnection line 170 may be formed by filling the upper interconnection trench 161 with a copper (Cu) material. Thus, the contact plug 140, the lower interconnection line 150, and the upper interconnection line 170 may be formed of copper (Cu), and the conductive pattern 11 may be formed of a material different from that of the contact plug 140. For example, the conductive pattern 11 may be formed of a titanium (Ti) material. The upper interconnection line 170 may be formed in contact with the top surface of the lower interconnection line 150. More specifically, the upper interconnection line 170 may be formed over the lower interconnection line 150 with an upper diffusion barrier layer 165 and an upper seed layer 166 interposed therebetween. The upper interconnection line 170 may have a plan view the same as that of the lower interconnection line 150. That is, the upper interconnection line 170 may have a width and a length the same as those of the lower interconnection line 150. Accordingly, the bottom surface of the upper interconnection line 170 may have a shape the same as that of the top surface or a bottom surface of the lower interconnection line 150. However, a width and a length of the upper interconnection line 170 may differ from those of the top surface of the lower interconnection line 150 by differences caused when a side surface of the upper interconnection line 170 is inclined during a process of etching the upper interconnection trench 161. Meanwhile, the upper interconnection line 170 may have a depth greater than that of the lower interconnection line 150.

Next, an interconnection line of a semiconductor device according to an example embodiment of the present inventive concept will be described.

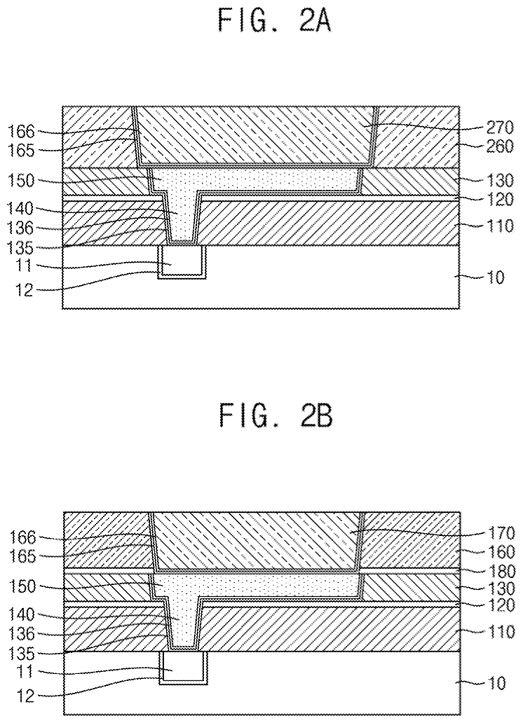

FIG. 2A is a vertical cross-sectional view of an interconnection line of a semiconductor device according to an example embodiment of the present inventive concept, and may correspond to FIG. 1I.

Referring to FIG. 2A, in the interconnection line of the semiconductor device, an upper interconnection line 270 may be formed to have a width greater than that of a lower interconnection line 150. A bottom surface of the upper interconnection line 270 may be in contact with the entire top surface of the lower interconnection line 150. A contact resistance between the upper interconnection line 270 and the lower interconnection line 150 may be further reduced. In this case, an upper interconnection trench 161 having a width greater than that of a lower interconnection trench 131 may be formed in a third interlayer insulating pattern 260 in which the upper interconnection line 270 is formed.

FIG. 2B is a vertical cross-sectional view of an interconnection line of a semiconductor device according to an example embodiment of the present inventive concept, and may correspond to FIG. 1I.

Referring to FIG. 2B, in the interconnection line of the semiconductor device, an upper etch stop pattern 180 may be further formed between a third interlayer insulating pattern 160 and a second interlayer insulating pattern 130. The upper etch stop pattern 180 may be formed of a material the same as that of an etch stop pattern 120 formed between a first interlayer insulating pattern 110 and the second interlayer insulating pattern 130. Referring to FIGS. 1F and 1G, when a position of an upper interconnection trench 161 deviates from a position of the lower interconnection trench 131 during a process of forming the upper interconnection trench 161 by etching the third interlayer insulating layer 160a, the second interlayer insulating pattern 130 may be further etched. In this case, the second interlayer insulating pattern 130 outside a lower interconnection line 150 may be unnecessarily etched, and thus, an upper diffusion barrier layer 165 and an upper seed layer 166 may be non-uniformly formed to thereby affect characteristics of an upper interconnection line 170. Accordingly, the upper etch stop pattern 180 may prevent the second interlayer insulating pattern 130 from being unnecessarily etched at a position adjacent to the lower interconnection line 150 during the process of forming the upper interconnection trench 161. As a result, the upper diffusion barrier layer 165, the upper seed layer 166, and the upper interconnection line 170 may be uniformly formed, thereby providing reliable electrical characteristics for the interconnection line of the semiconductor device. Meanwhile, after the upper interconnection trench 161 is formed, a portion of the upper etch stop pattern 180, which is located under the upper interconnection trench 161, may be etched using an additional etching process to expose a top surface of the lower interconnection line 150.

Interconnection structures of the semiconductor devices shown in FIGS. 2A and 2B described above may be equally applied to a method of fabricating an interconnection line of a semiconductor device according to an example embodiment of the present inventive concept described below.

Next, a method of fabricating an interconnection line of a semiconductor device according to an example embodiment of the present inventive concept will be described.

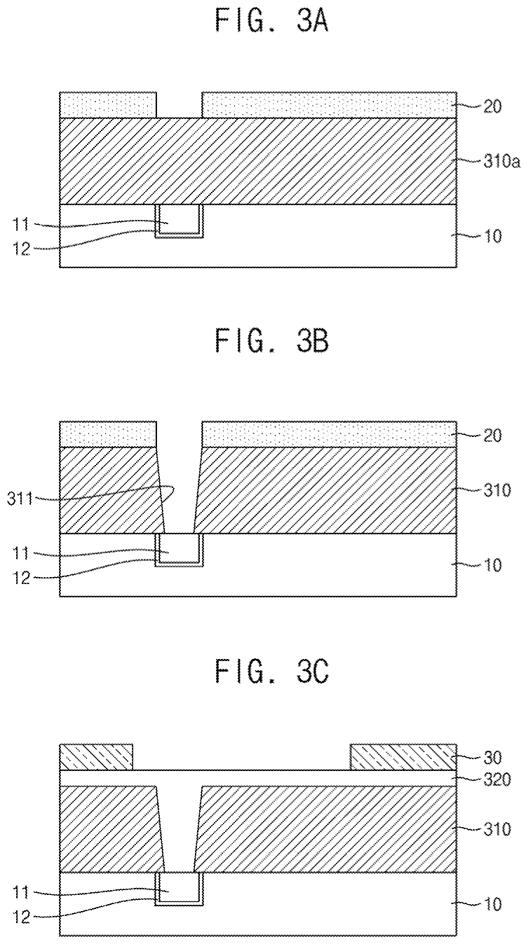

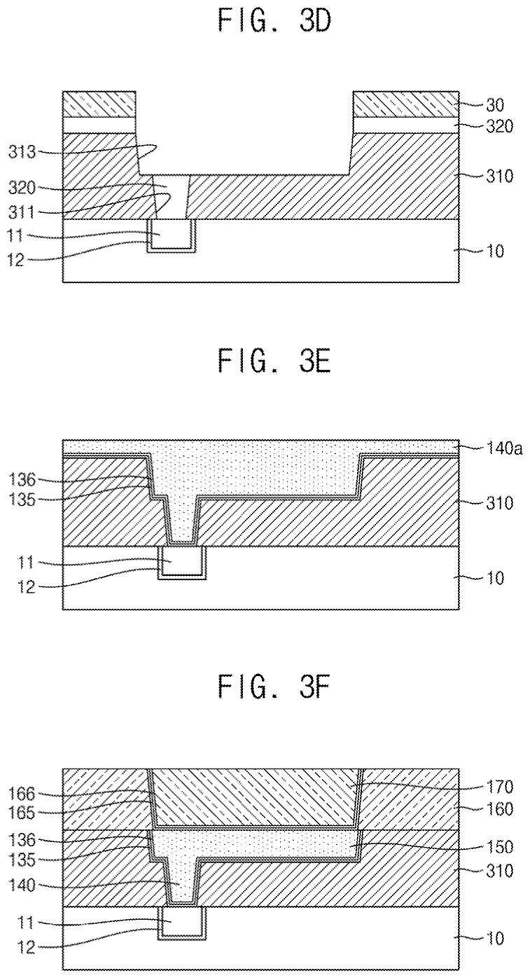

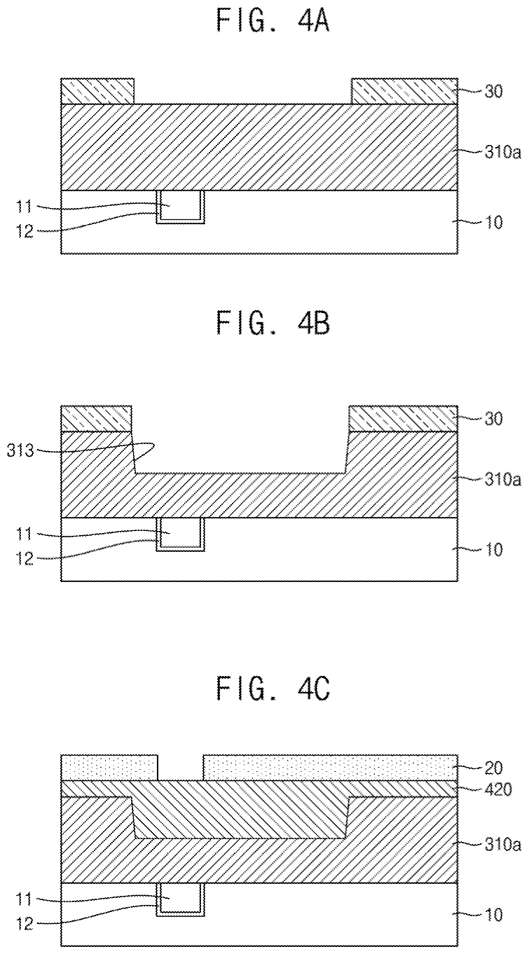

FIGS. 3A to 3F are vertical cross-sectional views illustrating processes of a method of fabricating an interconnection line of a semiconductor device according to an example embodiment of the present inventive concept.

The method of fabricating an interconnection line of a semiconductor device according to an example embodiment of the present inventive concept illustrated in FIGS. 3A-3F differs slightly from the method of fabricating an interconnection line of a semiconductor device according to FIGS. 1A to 1I in terms of operations of forming a contact plug 140 and a lower interconnection line 150. Accordingly, for convenience of explanation, the following description will focus on operations of forming the contact plug 140 and the lower interconnection line 150 in the method of fabricating an interconnection line of a semiconductor device. In addition, a detailed description of elements of the operations of forming the contact plug 140 and the lower interconnection line 150, which are the same as or similar to those of the method of fabricating an interconnection line of a semiconductor device according to FIGS. 1A to 1I, will be omitted. Furthermore, a detailed description of operation of forming an upper interconnection line 170 will be omitted.

Referring to FIG. 3A, a lower interlayer insulating layer 310a may be deposited on a substrate 10 and a conductive pattern 11, and a via photoresist pattern 20 may be formed on a top surface of the lower interlayer insulating layer 310a. A pattern diffusion barrier layer 12 may be formed on a bottom surface and a side surface of the conductive pattern 11.

Referring to FIG. 3B, the lower interlayer insulating layer 310a may be etched using the via photoresist pattern 20 as an etch mask to form a via 311. The lower interlayer insulating layer 310a may be anisotropically etched. The anisotropic etching process may include a RIE process. The via 311 may be formed to pass through the lower interlayer insulating layer 310a and expose a top surface of the conductive pattern 11. Due to the formation of the via 311, the lower interlayer insulating layer 310a may be patterned to form a lower interlayer insulating pattern 310.

Referring to FIG. 3C, a via filling layer 320 may be formed to fill the via 311 and cover the lower interlayer insulating pattern 310, and a lower photoresist pattern 30 may be formed on a region including the via filling layer 320 over the lower interlayer insulating pattern 310.

The via filling layer 320 may be deposited on a top surface of the lower interlayer insulating pattern 310 to fill the entire via 311. For example, the via filling layer 320 may be formed to a level higher than that of the top surface of the lower interlayer insulating pattern 310 to ensure that the entire via 311 is completely filled. The via filling layer 320 may be formed of a material capable of efficiently filling the via 311. Further, the via filling layer 320 may be formed of a material having an etch rate substantially higher than or equal to that of the lower interlayer insulating pattern 310. The via filling layer 320 may be formed of a material that is etched at a wet etch rate higher than that of the lower interlayer insulating pattern 310 during a wet etching process after the lower interconnection trench 313 is patterned. For example, the via filling layer 320 may be formed of an organic material or an inorganic material. The via filling layer 320 may be formed of an organic material including a spin-on-polymer (SOP) material such as, for example, a polyarylene ether-based material, a poly(methyl methacrylate) (PMMA)-based material, or a vinylether methacrylate-based material. Further, the via filling layer 320 may be formed of an inorganic material such as, for example, a hydrogen silsesquioxane (HSQ)-based material and/or a methyl silsesquioxane (MSQ)-based material.

Referring to FIG. 3D, the lower interlayer insulating pattern 310 and the via filling layer 320 may be etched to have a predetermined depth using the lower photoresist pattern 30 as an etch mask so that a lower interconnection trench 313 may be formed in the lower interlayer insulating pattern 310 over the via 311. The depth of the lower interconnection trench 313 may be determined in consideration of the height of the contact plug 140 and the thickness of the lower interconnection line 150 to be formed.

The lower interconnection trench 313 may be formed to have a predetermined depth from the top surface of the lower interlayer insulating pattern 310. The lower interconnection trench 313 may be formed to have a depth smaller than a depth of the remaining via 311. For example, the remaining via 311 may be connected to the conductive pattern 11 under the lower interconnection trench 313, and may be formed to have a depth greater than that of the lower interconnection trench 313. The lower interconnection trench 313 along with the remaining via 311 may form a dual Damascene structure.

Referring to FIG. 3E, the lower photoresist pattern 30 and the remaining via filling layer 320 may be removed. A lower diffusion barrier layer 135, a lower seed layer 136, and a lower interconnection layer 140a may be sequentially formed inside the via 311 and the lower interconnection trench 313.

The lower diffusion barrier layer 135 may be conformally deposited on a region including a top surface of the conductive pattern 11 and an inner side surface of the lower interlayer insulating pattern 310, which are exposed by the via 311, and an inner side surface and a top surface of the lower interlayer insulating pattern 310, which are exposed by the lower interconnection trench 313. The lower seed layer 136 may be conformally deposited on a surface of the lower diffusion barrier layer 135. The lower interconnection layer 140a may be deposited on the surfaces of the diffusion barrier layer 135 and the lower seed layer 136 to fill the via 311 and the lower interconnection trench 313. The lower interconnection layer 140a may be formed to a level higher than that of the top surface of the lower seed layer 136 to ensure that the via 311 and the lower interconnection trench 313 are completely filled. The lower diffusion barrier layer 135, the lower seed layer 136, and the lower interconnection layer 140a may also be formed on the top surface of the lower interlayer insulating pattern 310.

In the method of fabricating an interconnection line of a semiconductor device according to an example embodiment of the present inventive concept illustrated in FIGS. 3A to 3E, subsequent operations may be the same as or similar to those of FIGS. 1E to 1H. That is, the lower interconnection layer 140a may be planarized by a CMP process to form a contact plug 140 and a lower interconnection line 150. Thus, as described above, the contact plug 140 and the lower interconnection line 150 may be formed by a dual Damascene process. Further, a third interlayer insulating layer 160a, which may also be referred to as an upper interlayer insulating layer, may be deposited on top surfaces of the lower interlayer insulating pattern 310 and the lower interconnection line 150, and an upper photoresist pattern 40 may be formed on a top surface of the third interlayer insulating layer 160a. In addition, an upper interconnection trench 161 may be formed in the third interlayer insulating layer 160a using the upper photoresist pattern 40 as an etch mask, and may expose a top surface of the lower interconnection line 150. Furthermore, an upper diffusion barrier layer 165, an upper seed layer 166, and an upper interconnection layer 170a may be sequentially formed inside the upper interconnection trench 161. Further, the upper interconnection layer 170a may be planarized by a CMP process to form an upper interconnection line 170. In the method of fabricating an interconnection line of a semiconductor device according to the present example embodiment described above, both a via 311 and a lower interconnection trench 313 may be formed in a lower interlayer insulating layer 310a, while an etch stop layer may not be formed therebetween.

Referring to FIG. 3F, an interconnection line of a semiconductor device according to an example embodiment of the present inventive concept may include a lower interlayer insulating pattern 310, a contact plug 140, a lower interconnection line 150, a third interlayer insulating pattern 160 which may also be referred to as an upper interlayer insulating pattern, and an upper interconnection line 170.

The lower interlayer insulating pattern 310 may be deposited to have a predetermined thickness on a top surface of a substrate 10. The lower interlayer insulating pattern 310 may be formed to have a height corresponding to the entire height of the first interlayer insulating pattern 110, the etch stop pattern 120 and the second interlayer insulating pattern 130 of FIG. 1I. The entire lower interlayer insulating pattern 310 may be formed as one layer without forming an etch stop pattern 120 in the middle of the lower interlayer insulating pattern 310. The lower interlayer insulating pattern 310 may include a via 311, which is formed to have a predetermined height in an upward direction from a bottom surface of the lower interlayer insulating pattern 310, and a lower interconnection trench 313 formed to pass through a top surface of the via 311 from an upper portion of the via 311. The lower interconnection line 150 may be formed by filling the lower interconnection trench 313 with a copper (Cu) material. The lower interconnection line 150 may be integrally formed with the contact plug 140. The lower interconnection line 150 may have a predetermined width, length, and height. The third interlayer insulating pattern 160 and the upper interconnection line 170 illustrated in FIG. 3F may be the same as those included in the interconnection line of the semiconductor device according to the embodiment of FIG. 1I. Thus, as described above, the contact plug 140 and the lower interconnection line 150 may be formed by a dual Damascene process, and the upper interconnection line 170 may be formed by a single Damascene process.

Next, a method of fabricating an interconnection line of a semiconductor device according to an example embodiment of the present inventive concept will be described.

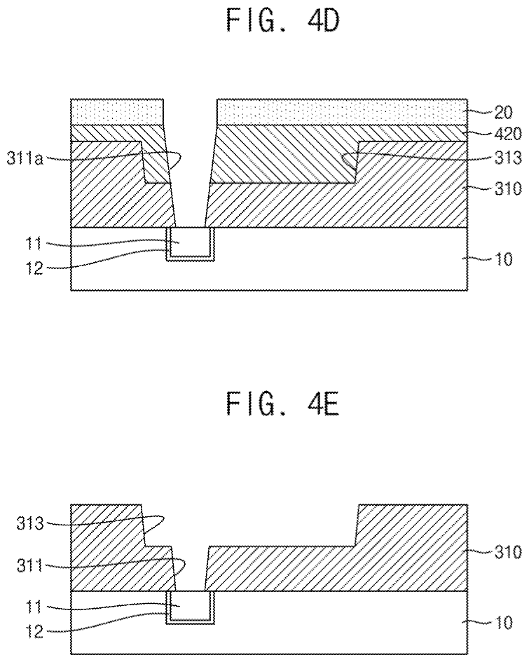

FIGS. 4A to 4E are vertical cross-sectional views illustrating processes of a method of fabricating an interconnection line of a semiconductor device according to an example embodiment of the present inventive concept.

The method of fabricating an interconnection line of a semiconductor device according to an example embodiment of the inventive concept illustrated in FIGS. 4A to 4E differs slightly from the method of fabricating an interconnection line of a semiconductor device of FIGS. 3A to 3E in terms of operations of forming a via 311 and a lower interconnection trench 313. Accordingly, for convenience of explanation, the following description will focus on operations of forming a via 311 and a lower interconnection trench 313 in the method of fabricating an interconnection line of a semiconductor device. In addition, a detailed description of elements of the operations of forming the via 311 and the lower interconnection trench 313, which are the same as or similar to those of the method of fabricating an interconnection line of a semiconductor device of FIGS. 3A to 3E, will be omitted. Furthermore, a detailed description of an operation of forming the upper interconnection line 170 will be omitted.

Referring to FIG. 4A, a lower interlayer insulating layer 310a may be deposited on a substrate 10 and a conductive pattern 11, and a lower photoresist pattern 30 may be formed on a top surface of the lower interlayer insulating layer 310a.

Referring to FIG. 4B, the lower interlayer insulating layer 310a may be etched to have a predetermined depth using the lower photoresist pattern 30 as an etch mask, thereby forming a lower interconnection trench 313. For example, the predetermined depth may be such a depth that the remaining thickness of the lower interlayer insulating layer 310a under the lower interconnection trench 313 may correspond to a height of a via to be formed in a subsequent process. The lower interconnection trench 313 may be formed downward from the top surface of the lower interlayer insulating layer 310a. The lower photoresist pattern 30 may be removed by a separate ashing process or strip process. Alternatively, the lower photoresist pattern 30 may be replaced by a hard mask layer. In this case, the hard mask layer may not be removed.

Referring to FIG. 4C, a lower trench filling layer 420 may be formed inside the lower interconnection trench 313, and a via photoresist pattern 20 may be formed on a top surface of the lower trench filling layer 420. The lower trench filling layer 420 may be formed to fill the entire lower interconnection trench 313. For example, the lower trench filling layer 420 may be formed to a level higher than that of the top surface of the lower interlayer insulating layer 310a to ensure that the lower interconnection trench 313 is completely filled. Thus, the lower trench filling layer 420 may also be formed on the top surface of the lower interlayer insulating layer 310a. The lower trench filling layer 420 may be formed of a material capable of efficiently filling the lower interconnection trench 313. In addition, the lower trench filling layer 420 may be formed of a material having an etch rate substantially higher than or equal to that of the lower interlayer insulating layer 310a. The lower trench filling layer 420 may be formed of a material that is etched at a rate higher than that of the lower interlayer insulating layer 310a during a wet etching process after the lower interconnection trench 313 is patterned. For example, the lower trench filling layer 420 may be formed of an organic material or an inorganic material. The lower trench filling layer 420 may be formed of a material the same as that of the above-described via filling layer 320.

Referring to FIG. 4D, the lower trench filling layer 420 and the lower interlayer insulating layer 310a may be sequentially etched using the via photoresist pattern 20 as an etch mask, thereby forming a via hole 311a passing through a bottom surface of the lower interlayer insulating layer 310a. The lower trench filling layer 420 and the lower interlayer insulating layer 310a may be anisotropically etched with a RIE process. Due to the formation of the via hole 311a, the lower interlayer insulating layer 310a may be patterned to form a lower interlayer insulating pattern 310. The via hole 311a may be formed to pass through the lower trench filling layer 420 and the lower interlayer insulating pattern 310 and expose a top surface of the conductive pattern 11.

Referring to FIG. 4E, the lower trench filling layer 420 and the via photoresist pattern 20 may be removed. The lower trench filling layer 420 and the via photoresist pattern 20 may be removed by an ashing process or a strip process having a high etch selectivity with respect to the lower interlayer insulating pattern 310. When the lower trench filling layer 420 is removed from the via hole 311a, a via 311 may be formed to pass through the lower interlayer insulating pattern 310 from a bottom surface of the lower interconnection trench 313 to a bottom surface of the lower interlayer insulating pattern 310. The via 311 may be connected to a lower portion of the lower interconnection trench 313 and formed to have a depth greater than that of the lower interconnection trench 313. The via 311 may expose the top surface of the conductive pattern 11. Accordingly, the via 311 and the lower interconnection trench 313 may be formed in the lower interlayer insulating pattern 310. The lower interconnection trench 313 and the via 311 may form a dual Damascene structure.

In the method of fabricating an interconnection line of a semiconductor device according to an example embodiment of the inventive concept illustrated in FIGS. 4A to 4E, subsequent operations may be the same as or similar to those of FIGS. 3E and 3F. Accordingly, a detailed description of subsequent processes will be omitted. In addition, since the interconnection line of the semiconductor device according to the example embodiment of the present inventive concept described above has a structure the same as that illustrated in FIG. 3F, a detailed description thereof will be omitted.

According to the example embodiments of the present inventive concept described above, an interconnection line can have a low resistance and be electrically connected to an underlying contact plug 140 and a substrate 10 or conductive pattern 11. Thus, the interconnection line of the semiconductor device can have high reliability.

While the example embodiments of the present inventive concept have been described with reference to the accompanying drawings, it should be understood by those skilled in the art that various modifications may be made without departing from the spirit and scope of the present inventive concept. Therefore, the above-described example embodiments should be considered in a descriptive sense only and not for purposes of limitation.

What is claimed is:

1. A method of fabricating an interconnection line of a semiconductor device, the method comprising:
depositing a first interlayer insulating layer, an etch stop layer, and a second interlayer insulating layer on a substrate in which a conductive pattern is formed, and forming a via photoresist pattern on a top surface of the second interlayer insulating layer;
forming a via in the first interlayer insulating layer, the etch stop layer, and the second interlayer insulating layer using the via photoresist pattern as an etch mask so as to form a first interlayer insulating pattern, an etch stop pattern, and a second interlayer insulating pattern, the via exposing a top surface of the substrate or the conductive pattern;
forming a lower photoresist pattern on a top surface of the second interlayer insulating pattern and forming a lower interconnection trench in the second interlayer insulating pattern using the lower photoresist pattern as an etch mask, the lower interconnection trench exposing portions of top surfaces of the via and the etch stop pattern;
forming a lower diffusion barrier layer, a lower seed layer, and a lower interconnection layer inside the via and the lower interconnection trench;
planarizing the lower interconnection layer using a chemical mechanical polishing (CMP) process to form a contact plug in the via and a lower interconnection line in the lower interconnection trench;
depositing a third interlayer insulating layer on top surfaces of the second interlayer insulating pattern and the lower interconnection line, and forming an upper photoresist pattern on a top surface of the third interlayer insulating layer;
forming an upper interconnection trench in the third interlayer insulating layer using the upper photoresist pattern as an etch mask to form a third interlayer insulating pattern, the upper interconnection trench exposing the top surface of the lower interconnection line;
forming an upper diffusion barrier layer, an upper seed layer, and an upper interconnection layer inside the upper interconnection trench; and
planarizing the upper interconnection layer using a CMP process to form an upper interconnection line.

2. The method of claim 1, wherein the lower interconnection trench is formed to have a depth smaller than that of the via and a width larger than that of the via.

3. The method of claim 1, wherein the upper interconnection trench is formed to have a height greater than that of the lower interconnection trench and to have a width greater than or equal to that of the lower interconnection trench.

4. The method of claim 1, wherein the contact plug and the lower interconnection line are integrally formed in a single process, and
the upper interconnection line is formed over the lower interconnection line with the upper diffusion barrier layer and the upper seed layer interposed therebetween.

5. The method of claim 1, wherein the upper photoresist pattern and the lower photoresist pattern are formed using a same photomask.

6. The method of claim 1, wherein the contact plug, the lower interconnection line, and the upper interconnection line are formed of copper, and the conductive pattern is formed of a material different from that of the contact plug.

7. The method of claim 1, wherein the lower diffusion barrier layer is formed on a region comprising the via exposing top surface of the substrate or the conductive pattern, and inner side surfaces of the first interlayer insulating pattern, the etch stop pattern, and the second interlayer insulating pattern, the lower seed layer is formed on a surface of the lower diffusion barrier layer, and the lower interconnection layer is formed to fill the via and the lower interconnection trench, and
the upper diffusion barrier layer is formed on a region comprising the upper interconnection trench exposing top surface of the lower interconnection line, and an inner side surface of the third interlayer insulating pattern, the upper seed layer is formed on a surface of the upper diffusion barrier layer, and the upper interconnection layer is formed to fill the upper interconnection trench.

8. The method of claim 1, wherein the contact plug and the lower interconnection line are formed by a dual Damascene process, and the upper interconnection line is formed by a single Damascene process.

9. A method of fabricating an interconnection line of a semiconductor device, the method comprising:
depositing a lower interlayer insulating layer on a substrate in which a conductive pattern is formed, and forming a via photoresist pattern on a top surface of the lower interlayer insulating layer;
forming a via in the lower interlayer insulating layer using the via photoresist pattern as an etch mask to form a lower interlayer insulating pattern, the via exposing a top surface of the substrate or the conductive pattern;
forming a via filling layer in the via and forming a lower photoresist pattern on a region comprising the via filling layer over the lower interlayer insulating pattern;
etching the lower interlayer insulating pattern and the via filling layer using the lower photoresist pattern as an etch mask to form a lower interconnection trench in the lower interlayer insulating pattern on the via;
removing the lower photoresist pattern and the via filling layer remaining in the via and forming a lower diffusion barrier layer, a lower seed layer, and a lower interconnection layer inside the via and the lower interconnection trench;
planarizing the lower interconnection layer using a chemical mechanical polishing (CMP) process to form a contact plug in the via and a lower interconnection line in the lower interconnection trench;
depositing an upper interlayer insulating layer on top surfaces of the lower interlayer insulating pattern and the lower interconnection line, and forming an upper photoresist pattern on a top surface of the upper interlayer insulating layer;
forming an upper interconnection trench in the upper interlayer insulating layer using the upper photoresist pattern as an etch mask, the upper interconnection trench exposing the top surface of the lower interconnection line;
forming an upper diffusion barrier layer, an upper seed layer, and an upper interconnection layer inside the upper interconnection trench; and
planarizing the upper interconnection layer using a CMP process to form an upper interconnection line.

10. The method of claim 9, wherein the via filling layer is formed of a material having an etch rate higher than or equal to that of the lower interlayer insulating layer.

11. The method of claim 9, wherein the lower interconnection trench is connected to the via at an upper portion of the via and formed to have a depth smaller than that of the via.

12. The method of claim 9, wherein the upper interconnection trench is formed to have a depth greater than that of the lower interconnection trench, and
the upper interconnection line is formed to have a height greater than that of the lower interconnection line.

13. The method of claim 9, wherein the upper photoresist pattern and the lower photoresist pattern are formed using a same photomask.

14. A method of fabricating an interconnection line of a semiconductor device, the method comprising:
depositing a lower interlayer insulating layer on a substrate in which a conductive pattern is formed, and forming a lower photoresist pattern on a top surface of the lower interlayer insulating layer;
forming a lower interconnection trench in the lower interlayer insulating layer using the lower photoresist pattern as an etch mask;
forming a lower trench filling layer inside the lower interconnection trench and forming a via photoresist pattern on a top surface of the lower trench filling layer;
etching the lower trench filling layer and the lower interlayer insulating layer using the via photoresist pattern as an etch mask to form a via hole passing through a bottom surface of the lower interlayer insulating layer so that the lower interlayer insulating layer is patterned to form a lower interlayer insulating pattern;
removing the lower trench filling layer and the via photoresist pattern and forming a via in the lower interlayer insulating pattern;
forming a lower diffusion barrier layer, a lower seed layer, and a lower interconnection layer inside the via and the lower interconnection trench;
planarizing the lower interconnection layer using a chemical mechanical polishing (CMP) process to form a contact plug in the via and a lower interconnection line in the lower interconnection trench;
depositing an upper interlayer insulating layer on top surfaces of the lower interlayer insulating pattern and the lower interconnection line and forming an upper photoresist pattern on a top surface of the upper interlayer insulating layer;
forming an upper interconnection trench in the upper interlayer insulating layer using the upper photoresist pattern as an etch mask, the upper interconnection trench exposing the top surface of the lower interconnection line;
forming an upper diffusion barrier layer, an upper seed layer, and an upper interconnection layer inside the upper interconnection trench; and
planarizing the upper interconnection layer using a CMP process to form an upper interconnection line.

15. The method of claim 14, wherein the lower trench filling layer is formed of a material having an etch rate higher than or equal to that of the lower interlayer insulating layer.

16. The method of claim 14, wherein the via is connected to the conductive pattern under the lower interconnection trench and formed to have a depth greater than that of the lower interconnection trench.

17. The method of claim 14, wherein the lower trench filling layer is further formed on the top surface of the lower interlayer insulating layer.

18. The method of claim 14, wherein the upper interconnection trench is formed to have a depth greater than that of the lower interconnection trench, and
the upper interconnection line is formed to have a height greater than that of the lower interconnection line.

19. The method of claim 14, wherein the upper photoresist pattern and the lower photoresist pattern are formed using a same photomask.

20. The method of claim 14, wherein the contact plug, the lower interconnection line, and the upper interconnection line are formed of copper, and the conductive pattern is formed of a material different from that of the contact plug.
